(19) United States
(12) Patent Application Publication
(10) Pub. No.: US 2026/0262395 A1
(43) Pub. Date: Sep. 3, 2026

(54) DISPLAY PANEL AND DISPLAY APPARATUS

(71) Applicants: Beijing BOE Technology Development Co., Ltd., Beijing (CN); BOE Technology Group Co., Ltd., Beijing (CN)

(72) Inventors: Bo XU, Beijing (CN); Cheng HAN, Beijing (CN); Yansong LI, Beijing (CN); Xu LI, Beijing (CN); Hao GAO, Beijing (CN); Qixiao WU, Beijing (CN); Yang XIANG, Beijing (CN); Bingwei YANG, Beijing (CN); Shun WANG, Beijing (CN); Zhiyu HUANG, Beijing (CN)

(21) Appl. No.: 18/865,114

(22) PCT Filed: Aug. 23, 2024
(86) PCT No.: PCT/CN2024/114354

§ 371 Date: Nov. 12, 2024

(30) Foreign Application Priority Data
Sep. 26, 2023 (CN) 202311257404.4

(51) Int. Cl. H10K 59/124; H10K 59/122; H10K 59/80

(52) U.S. Cl. CPC H10K 59/124; H10K 59/122; H10K 59/879

(57) ABSTRACT

Provided is a display panel. The display panel includes a substrate, an insulating layer disposed on the substrate, and a plurality of light-emitting units disposed on the insulating layer. Each of the light-emitting units includes a first electrode layer, a light-emitting layer, and a second electrode layer. In the present disclosure, a surface of the insulating layer distal from the substrate has a plurality of curved surface structures, and the plurality of light-emitting units is disposed on the plurality of curved surface structures in one-to-one correspondence.

The present disclosure is a U.S. national stage of international application No. PCT/CN2024/114354, filed on Aug. 23, 2024, which claims priority to Chinese Patent Application No. 202311257404.4, filed on Sep. 26, 2023, and entitled “DISPLAY PANEL AND DISPLAY APPARATUS”, the entire contents of which are incorporated herein by reference.

### TECHNICAL FIELD

The present disclosure relates to the field of display technologies, and particularly relates to, a display panel and a display apparatus.

### BACKGROUND

A display panel is of a structure having an image display function.

A display panel includes a base substrate, a planarization layer and a conductive circuit disposed on the base substrate, and a plurality of light-emitting units disposed on the planarization layer, wherein the planarization layer covers the conductive circuit, the shape of each of the plurality of light-emitting units disposed on the planarization layer is planar, and the conductive circuit transmits electrical signals for the plurality of light-emitting units.

### SUMMARY

A display panel is provided according to embodiments of the present disclosure. The display panel includes:
a substrate;
an insulating layer disposed on the substrate, wherein a surface, distal from the substrate, of the insulating layer is provided with a plurality of curved surface structures; and
a plurality of light-emitting units disposed on the plurality of curved surface structures in one-to-one correspondence, wherein each of the light-emitting units includes a first electrode layer, a light-emitting layer, and a second electrode layer, the first electrode layer is disposed on a curved surface structure corresponding to the light-emitting unit, the light-emitting layer is disposed on a side, distal from the curved surface structure, of the first electrode layer, and the second electrode is disposed on a side, distal from the curved surface structure, of the light-emitting layer.

In some embodiments, the plurality of curved surface structures includes first convex curved surface structures protruding towards a direction distal from the substrate, first concave curved surface structures recessed towards a direction proximal to the substrate, or both.

In some embodiments, the display panel further includes a first light modulation layer disposed on a side, distal from the substrate, of the light-emitting units, wherein the first light modulation layer includes a first low-refractive layer and a first high-refractive layer which are laminated, the first high-refractive layer is disposed on a side, distal from the substrate, of the first low-refractive layer, and a refractive index of the first low-refractive layer is smaller than a refractive index of the first high-refractive layer; and
a surface, distal from the substrate, of the first low-refractive layer is provided with second concave curved surface structures recessed towards the direction proximal to the substrate, and a surface, proximal to the substrate, of the first high-refractive layer is provided with second convex curved surface structures protruding towards the direction proximal to the substrate, the second concave curved surface structures and the second convex curved surface structures are complementary structures, and the second convex curved surface structures are disposed in the second concave curved surface structures; and
orthogonal projections of the light-emitting units on the substrate overlap with orthogonal projections of the second concave curved surface structures of the first low-refractive layer on the substrate.

In some embodiments, the display panel further includes a packaging layer disposed on the side, distal from the substrate, of the light-emitting units, and the first light modulation layer is disposed on a side, distal from the light-emitting units, of the packaging layer.

In some embodiments, the display panel further includes a packaging layer and a first light modulation layer, wherein the packaging layer includes a first inorganic packaging layer, an organic packaging layer, and a second inorganic packaging layer which are laminated on the side, distal from the substrate, of the light-emitting units, the first light modulation layer is disposed between the first inorganic packaging layer and the organic packaging layer, and includes a first low-refractive layer, and a refractive index of the first low-refractive layer is smaller than a refractive index of the organic packaging layer; and
a surface, distal from the substrate, of the first low-refractive layer is provided with second concave curved surface structures recessed towards the direction proximal to the substrate, a surface, proximal to the substrate, of the organic packaging layer is provided with second convex curved surface structures protruding towards the direction proximal to the substrate, the second concave curved surface structures and the second convex curved surface structures are complementary structures, and the second convex curved surface structures are disposed in the second concave curved surface structures;
orthogonal projections of the light-emitting units on the substrate overlap with orthogonal projections of the second concave curved surface structures of the first low-refractive layer on the substrate.

In some embodiments, the display panel further includes a second light modulation layer, disposed on a side, distal from the substrate, of the packaging layer, wherein the second light modulation layer includes a second high-refractive layer and a second low-refractive layer which are laminated, and a refractive index of the second low-refractive layer is smaller than a refractive index of the second high-refractive layer; and
a surface, proximal to the substrate, of the second low-refractive layer is provided with third concave curved surface structures recessed towards the direction distal from the substrate, a surface, distal from the substrate, of the second high-refractive layer is provided with third convex curved surface structures protruding towards the direction distal from the substrate, the third concave curved surface structures and the third convex curved surface structures are complementary structures, and the third convex curved surface structures are disposed in the third concave curved surface structures; and
the orthogonal projections of the light-emitting units on the substrate overlap with orthogonal projections of the third concave curved surface structures of the second low-refractive layer on the substrate.

In some embodiments, the orthogonal projections of the third concave curved surface structures of the second low-refractive layer on the substrate overlap with the orthogonal projections of the second concave curved surface structures of the first low-refractive layer on the substrate.

In some embodiments, the display panel further includes a pixel definition layer, disposed in a region of the surface, distal from the substrate, of the insulating layer that does not have the curved surface structure; and
the pixel definition layer includes a reflective material, or the first inorganic packaging layer covers the pixel definition layer and a refractive index of the pixel definition layer is smaller than a refractive index of the first inorganic packaging layer.

In some embodiments, the orthographic projections of the light-emitting units on the substrate are disposed in the orthographic projections of the second concave curved surface structures on the substrate, and an orthographic projection of an edge of each light-emitting unit on the substrate is spaced from an orthographic projection of an edge of second concave curved surface structure corresponding to the light-emitting unit on the substrate.

In some embodiments, the display panel satisfies: h1/v1≤h2/v2<0.5,
wherein h1 is a maximum height difference between a region of the surface, distal from the substrate, of the insulating layer that has the curved surface structures and a region of the surface, distal from the substrate, of the insulating layer that does not have the curved surface structure in a first direction perpendicular to the substrate, v1 is a maximum width of the curved surface structures of the insulating layer in a direction parallel to the substrate, h2 is a maximum height difference between a region of the surface, distal from the substrate, of the first low-refractive layer that has the second concave curved surface structures and a region of the surface, distal from the substrate, of the first low-refractive layer that does not have the second concave curved surface structure in the first direction, and v2 is a maximum width of the second concave curved surface structures of the first low-refractive layer in the direction parallel to the substrate.

In some embodiments, the display panel further includes a pixel definition layer disposed on a side, distal from the substrate, of the insulating layer, and the pixel definition layer is disposed between the plurality of curved surface structures; and

the display panel satisfies: H<D=tan(v1/2 h1)*(g+v1)/2, wherein H is a minimum distance between the second concave curved surface structures of the first low-refractive layer and the light-emitting units in a first direction perpendicular to the substrate; D is a minimum distance between a color mixing point and the pixel definition layer in the first direction, and the color mixing point is a point at which light rays that do not irradiate the pixel definition layer in light rays emitted from the two adjacent light-emitting units in the plurality of light-emitting units intersect; h1 is a maximum height difference between the region of the surface, distal from the substrate, of the insulating layer that has the curved surface structures and the region of the surface, distal from the substrate, of the insulating layer that does not have the curved surface structure in the first direction; v1 is a maximum width of the curved surface structures of the insulating layer in a direction parallel to the substrate; and g is a distance between two adjacent light-emitting units in the direction parallel to the substrate.

In some embodiments, the surface, distal from the substrate, of the insulating layer is provided with a plurality of first concave curved surface structures recessed towards the direction proximal to the substrate; and

a thickness of a region of the surface, distal from the substrate, of the insulating layer that does not have the curved surface structure ranges from 3 microns to 5 microns, and a thickness of a region of the surface, distal from the substrate, of the insulating layer that has the curved surface structures is greater than or equal to 1 micron.

In some embodiments, a maximum height difference between a region of the surface, distal from the substrate, of the insulating layer that has the curved surface structures and a region of the surface, distal from the substrate, of the insulating layer that does not have the curved surface structure in a first direction perpendicular to the substrate is greater than 0 microns and less than or equal to 2 microns.

In some embodiments, the display panel further includes conductive circuits disposed on the substrate, wherein the insulating layer covers the conductive circuits, and orthogonal projections of the curved surface structures on the substrate overlap with orthogonal projections of the conductive circuits on the substrate.

According to some embodiments of the present disclosure, a display apparatus is provided, wherein the display apparatus includes a housing and the display panel as described in any of above embodiments, and the display panel is disposed in the housing.

### BRIEF DESCRIPTION OF DRAWINGS

For clearer descriptions of the technical solutions in the embodiments of the present disclosure, the following briefly introduces the accompanying drawings required for describing the embodiments. Apparently, the accompanying drawings in the following description show merely some embodiments of the present disclosure, and those skilled in the art may still derive other drawings from these accompanying drawings without creative efforts.

FIG. 1 is a schematic structural diagram of a display panel;

FIG. 2 is a schematic structural diagram of a display panel according to some embodiments of the present disclosure;

FIG. 3 is a schematic structural diagram of another display panel according to some embodiments of the present disclosure;

FIG. 4 is a schematic structural diagram of another display panel according to some embodiments of the present disclosure;

FIG. 5 is a schematic structural diagram of another display panel according to some embodiments of the present disclosure;

FIG. 6 is a schematic structural diagram of another display panel according to some embodiments of the present disclosure;

FIG. 7 is a schematic structural diagram of another display panel according to some embodiments of the present disclosure;

FIG. 8 is a schematic partial structural diagram of another display panel according to some embodiments of the present disclosure;

FIG. 9 is a schematic partial structural diagram of another display panel according to some embodiments of the present disclosure;

FIG. 10 is a schematic structural diagram of another display panel according to some embodiments of the present disclosure;

FIG. 11 is a schematic principal diagram of a polarization structure layer provided according to some embodiments of the present disclosure;

FIG. 12 is a schematic top view of circular light-emitting units with curved surface structures according to some embodiments of the present disclosure;

FIG. 13 is a schematic top view of square light-emitting units with curved surface structures according to some embodiments of the present disclosure;

FIG. 14 is a schematic top view of rectangular light-emitting units with curved surface structures according to some embodiments of the present disclosure; and

FIG. 15 is a schematic top view of hexagonal light-emitting units with curved surface structures according to some embodiments of the present disclosure.

Explicit embodiments of the present disclosure have been shown through the accompanying drawings, which will be described in more detail below. These drawings and descriptions are not intended to limit the scope of the concept of the present disclosure by any means, but rather to illustrate the concept of the present disclosure for those skilled in the art by reference to specific embodiments.

### DETAILED DESCRIPTION

For clearer descriptions of the objectives, technical solutions, and advantages of the present disclosure, the embodiments of the present disclosure are described in detail hereinafter with reference to the accompanying drawings.

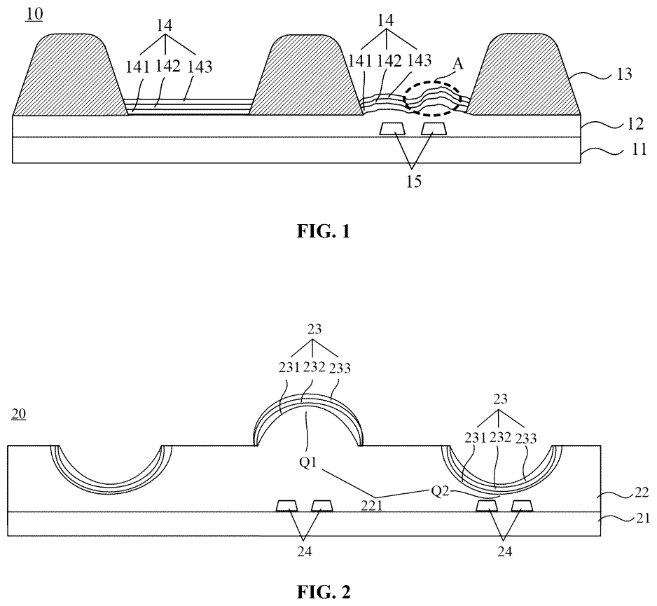

FIG. 1 provides a schematic structural diagram of a display panel. Referring to FIG. 1, the display panel 10 includes: a substrate 11; a planarization layer 12 disposed on the substrate 11; a plurality of pixel definition layers 13 disposed on a surface of the planarization layer 12 distal from the substrate 11; a plurality of light-emitting units 14, wherein the light-emitting units 14 are all disposed in a region of a surface, without the pixel definition layers, of the planarization layer 12 distal from the substrate 11, each of the light-emitting units 14 includes a first electrode layer 141, a light-emitting layer 142 and a second electrode layer 143, the first electrode layer 141 is disposed on the planarization layer 12, the light-emitting layer 142 is disposed on a side of the first electrode layer 141 distal from the planarization layer 12, and the second electrode 143 is disposed on a side of the light-emitting layer 142 distal from the planarization layer 12; and conductive circuits 15, wherein the conductive circuits 15 are disposed on the substrate 11, and the planarization layer 12 covers the conductive circuits 15.

The shape of each of the plurality of light-emitting units 14 disposed on the planarization layer 12 is planar. However, the actual light-emitting area of the planar light-emitting unit 14 is small, resulting in poorer luminance of the display panel 10.

In addition, since each of the conductive circuits 15 itself is in a convex shape and the planarization layer 12 covers the conductive circuits 15, the planarization layer 12 forms an irregular protrusion or depression that is difficult to control as shown in region A, leading to non-flat and nonuniform surfaces of the plurality of light-emitting units 14 disposed on the planarization layer 12. As a result, the display panel 10 suffers from problems such as nonuniform luminance and color cast.

A display panel is provided according to the embodiments of the present disclosure. Please refer to FIG. 2, which is a schematic structural diagram of the display panel according to some embodiments of the present disclosure. The display panel 20 includes a substrate 21; an insulating layer 22 disposed on the substrate 21, wherein a surface of the insulating layer 22 distal from the substrate 21 is provided with a plurality of curved surface structures 221; and a plurality of light-emitting units 23 disposed on the plurality of curved surface structures 221 in one-to-one correspondence, wherein each of the light-emitting units 23 includes a first electrode layer 231, a light-emitting layer 232 and a second electrode layer 233, the first electrode layer 231 is disposed on the corresponding curved surface structure 221, the light-emitting layer 232 is disposed on a side of the first electrode layer 231 distal from the curved surface structure 221, and the second electrode 233 is disposed on a side of the light-emitting layer 232 distal from the curved surface structure 221. Therefore, the light-emitting layer 232 is in the shape of a curved surface, which has a larger light-emitting area than a planar light-emitting layer.

In summary, a display panel including a substrate, an insulating layer, and a plurality of light-emitting units is provided according to the embodiments of the present disclosure, wherein a surface of the insulating layer distal from the substrate has a plurality of curved surface structures, and the plurality of light-emitting units is disposed on the plurality of curved surface structures in one-to-one correspondence. In this way, an electrode and a light-emitting layer of the light-emitting unit disposed on the corresponding curved surface structure are in the shape of a curved surface, and the electrode drives the light-emitting layer in the shape of the curved surface to emit light rays. Compared with a light-emitting unit in the shape of a planar surface, the light-emitting unit in the shape of a curved surface has a larger light-emitting area, such that the luminance is improved, and a problem of poorer luminance of display panels in the related art is solved, thereby achieving an effect of improving the luminance of the display panel.

In some embodiments, the plurality of curved surface structures includes first convex curved surface structures protruding towards a direction distal from the substrate, first concave curved surface structures recessed towards a direction proximal to the substrate, or both. In some exemplary embodiments, the plurality of curved surface structures 221 in FIG. 2 includes first convex curved surface structures Q1 protruding towards the direction distal from the substrate 21 and first concave curved surface structures Q2 recessed towards the direction proximal to the substrate. Both the first convex curved surface structures Q1 and the first concave curved surface structures Q2 increase the surface area of the light-emitting layer 232 of the light-emitting unit 23, such that the actual light-emitting area is increased, thereby improving the luminance of the display panel 20.

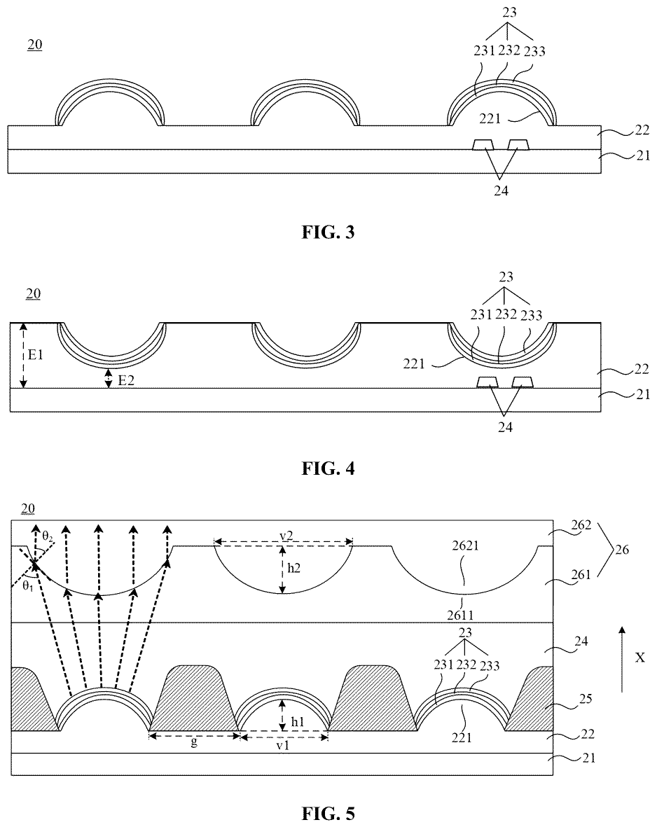

The display panel according to the embodiments of the present disclosure may also include only one of the curved surface structures. Please refer to FIGS. 3 and 4. FIG. 3 is a schematic structural diagram of a display panel including first convex curved surface structures according to some embodiments of the present disclosure, and FIG. 4 is a schematic structural diagram of a display panel including first concave curved surface structures according to some embodiments of the present disclosure. The curved surface structure shown in FIG. 3 is the first convex curved surface structure 221 protruding towards the direction distal from the substrate 21, and the curved surface structure shown in FIG. 4 is the first concave curved surface structure 221 recessed towards the direction proximal to the substrate 21. The display panel 20 further includes conductive circuits 24 disposed on the substrate 21. The insulating layer 22 covers the conductive circuits 24. The conductive circuits 24 transmit electrical signals for the plurality of light-emitting units 23. Orthogonal projections of the curved surface structures 221 on the substrate 21 overlap with orthogonal projections of the conductive circuits 24 on the substrate 21. That is, the conductive circuits 24 are disposed below the curved surface structures 221.

The conductive circuit 24 itself is in a convex shape. For the display panel shown in FIG. 3, the insulating layer 22 includes a plurality of first convex curved surface structures 221 protruding towards the direction distal from the substrate 21. In this way, the distance between the light-emitting units 23 and the conductive circuits 24 is increased, such that the adverse influence of the convex conductive circuits 24 on the surface appearance of the light-emitting units 23 is avoided, thereby improving the uniformity of the luminance of the display panel 20 and the homogeneity of color cast at different viewing angles.

For the display panel shown in FIG. 4, the insulating layer 22 includes a plurality of first concave curved surface structures 221 recessed towards the direction proximal to the substrate 21. A flat insulating layer is formed on the substrate 21, and then the first concave curved surface structures 221 are manufactured by etching the flat insulating layer, such that the bottom appearances of the first concave curved surface structures 221 are not influenced by the convex conductive circuits 24, thereby avoiding the adverse influence of the conductive circuits 24 on the surface appearances of the light-emitting units 23, and improving the uniformity of the luminance of the display panel 20 and the homogeneity of color cast at different viewing angles. In addition, the thickness E1 of the region of the surface of the insulating layer 22 distal from the substrate 21 that does not have the first concave curved surface structures 221 ranges from 3 microns to 5 microns, and the range of the minimum thickness E2 of the region of the surface of the insulating layer 22 distal from the substrate 21 that has the first concave curved surface structures 221 is greater than or equal to 1 micron. The increase in the overall thickness of the insulating layer 22 facilitates the etching process for manufacturing the first concave curved surface structures 221. The guaranteed certain thickness of the region of the surface of the insulating layer 22 distal from the substrate 21 that has the first concave curved surface structures 221 enables the bottoms of the first concave curved surface structures 221 to be spaced from the conductive circuits 24, thereby reducing electromagnetic crosstalk or leakage between the lower conductive circuits 24 and the first electrodes 231 of the light-emitting units 23.

The display panel according to the embodiments of the present disclosure may be an organic light-emitting diode (OLED) display panel; and for each light-emitting unit of the plurality of light-emitting units 23, the first electrode layer 231 and the second electrode layer 233 cooperate with each other to drive the light-emitting layer 232. The first electrode layer 231 is an anode, the second electrode layer 233 is a cathode, and the light-emitting layer 232 is an organic light-emitting layer. In addition, a hole injection layer, a hole transport layer, and an electron barrier layer are further sequentially laminated between the first electrode layer 231 and the light-emitting layer 232, and a hole barrier layer, an electron transport layer, and an electron injection layer are further sequentially laminated between the light-emitting layer 232 and the second electrode layer 233. Holes are injected into the light-emitting layer 232 from the first electrode layer 231, and electrons are injected into the light-emitting layer 232 from the second electrode layer 233. Finally, the holes and electrons recombine in the light-emitting layer 232 to generate excitons. When the generated excitons are relaxed from an excited state to a ground state, energy is released to generate photons.

Light rays emitted from the light-emitting units of the curved surfaces according to the embodiments of the present disclosure are divergent light rays, and the divergent light rays are collimated by a first light modulation layer. Please refer to FIG. 5, which is a schematic structural diagram of another display panel including a first light modulation layer according to some embodiments of the present disclosure. The display panel 20 includes a substrate 21, an insulating layer 22, and a plurality of light-emitting units 23. Please refer to the embodiment of FIG. 2 for details.

The display panel 20 further includes a first light modulation layer 26. The first light modulation layer 26 is disposed on a side of the light-emitting unit 23 distal from the substrate 21, and includes a first low-refractive layer 261 and a first high-refractive layer 262 which are laminated. The first high-refractive layer 262 is disposed on a side of the first low-refractive layer 261 distal from the substrate 21, and the refractive index of the first low-refractive layer 261 is smaller than that of the first high-refractive layer 262. A surface of the first low-refractive layer 261 distal from the substrate 21 is provided with a plurality of second concave curved surface structures 2611 recessed towards the direction proximal to the substrate 21, and a surface of the first high-refractive layer 262 proximal to the substrate 21 is provided with a plurality of second convex curved surface structures 2621 protruding towards the direction proximal to the substrate 21.

After the divergent light rays emitted from the light-emitting unit 23 reach the first light modulation layer 26, the light rays are refracted from the first low-refractive layer 261 (an optically thinner medium) to the first high-refractive layer 262 (an optically denser medium). According to Snell's Law:

$${n}_{1} sin {θ}_{1} = {n}_{2} sin {θ}_{2} .$$

Since the refractive index of the first low-refractive layer 261 is smaller than that of the first high-refractive layer 262, the incident angle θ₁ is larger than the refractive angle θ₂. Combined with the curved surface appearance of the second concave curved surface structure 2611, after reaching the first light modulation layer 26, the light rays are emitted in a direction towards the normal, that is, the light rays are collimated, which effectively improves the light-emitting efficiency and improves the luminance of the display panel. The refractive index n₁ of the first low-refractive layer 261 ranges from 1.45 to 1.55, and the refractive index n₂ of the first high-refractive layer 262 ranges from 1.65 to 1.85.

In addition, the second concave curved surface structure 2611 and the second convex curved surface structure 2621 are complementary structures, and the second convex curved surface structure 2621 is disposed in the second concave curved surface structure 2611. In this way, it is ensured that the first low-refractive layer 261 and the first high-refractive layer 262 are closely attached to each other, thereby avoiding the light ray loss caused by a gap.

The orthographic projection of the light-emitting unit 23 on the substrate 21 overlaps with the orthographic projection of the second concave curved surface structure 2611 of the first low-refractive layer 261 on the substrate 21. That is, a partial region of the light-emitting unit 23 directly faces the second concave curved surface structure 2611 of the first low-refractive layer 261. In this way, part of the light rays emitted from the light-emitting unit 23 is collimated by the first light modulation layer 26, thereby improving the light-emitting efficiency of the front surface.

The display panel 20 shown in FIG. 5 may further include a packaging layer 24 disposed on the side of the light-emitting units 23 distal from the substrate 21, and the first light modulation layers 26 are disposed on a side of the packaging layer 24 distal from the light-emitting unit 23. The packaging layer 24 is configured to protect the light-emitting units 23 and prevent external moisture or oxygen from penetrating into the light-emitting units 23.

The display panel 20 further includes pixel definition layers 25 disposed in a region of the surface of the insulating layer 22 distal from the substrate 22 that does not have the curved surface structure 221. The pixel definition layers 25 are configured to define the positions of the plurality of light-emitting units 23 on the insulating layer 22. The width of the side of each pixel definition layer 25 distal from the insulating layer 22 is smaller than that of the side of the pixel definition layer 25 proximal to the insulating layer 22, which prevents wide-angle light rays emitted from the light-emitting units 23 from being blocked by the pixel definition layers 25. In this way, more light rays emitted from the light-emitting units 23 reach the next film layer.

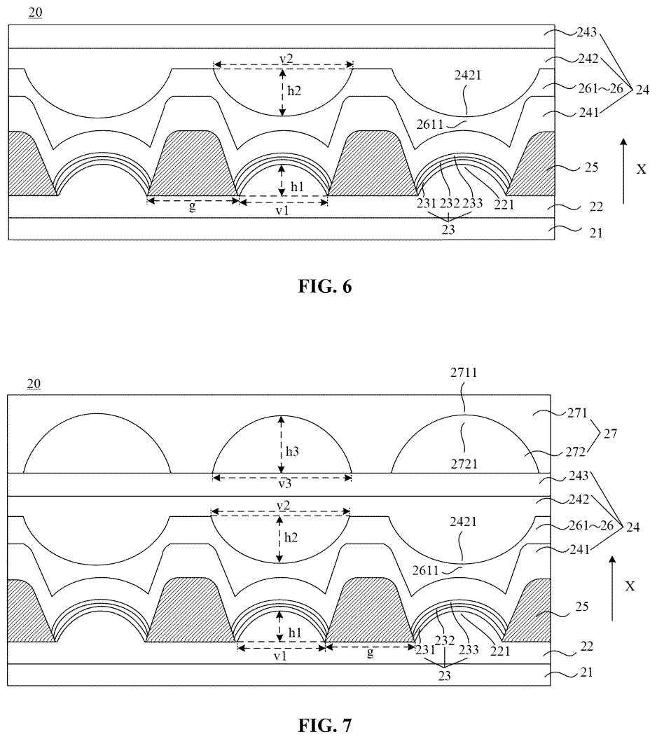

The forgoing is the case where the first light modulation layer is disposed on the side of the packaging layer distal from the light-emitting unit, and the first light modulation layer may also be disposed in the packaging layer. In some exemplary embodiments, please refer to FIG. 6, which is a schematic structural diagram of another display panel in which a first light modulation layer is disposed in a packaging layer according to some embodiments of the present disclosure. The display panel 20 includes a substrate 21, an insulating layer 22, a plurality of light-emitting units 23, and pixel definition layers 25. Please refer to the embodiment of FIG. 5 for details.

The display panel 20 further includes a packaging layer 24 disposed on a side of the light-emitting units 23 distal from the substrate 21. The packaging layer 24 includes a first inorganic packaging layer 241, an organic packaging layer 242, and a second inorganic packaging layer 243 which are laminated on the side of the light-emitting units 23 distal from the substrate 21. The packaging layer 24 is configured to protect the light-emitting units 23 and prevents external moisture or oxygen from penetrating into the light-emitting units 23.

The display panel 20 further includes a first light modulation layer 26 disposed between the first inorganic packaging layer 241 and the organic packaging layer 242. The first light modulation layer 26 includes a first low-refractive layer 261, and a refractive index of the first low-refractive layer 261 is smaller than that of the organic packaging layer 242. A surface of the first low-refractive layer 261 distal from the substrate 21 is provided with a plurality of second concave curved surface structures 2611 recessed towards the direction proximal to the substrate 21, and a surface of the organic packaging layer 242 proximal to the substrate 21 is provided with a plurality of second convex curved surface structures 2421 protruding towards the direction proximal to the substrate 21. The second concave curved surface structures 2611 and the second convex curved surface structures 2421 are complementary structures, and the second convex curved surface structures 2421 are disposed in the second concave curved surface structures 2611.

Since light rays emitted from the light-emitting layers 232 pass through multiple dielectric surfaces of organic and inorganic layers which have different refractive indexes, it will cause light loss in various modes, such as metal loss and surface plasmon loss caused by metal electrodes, waveguide mode loss caused by transparent electrodes, and cover plate mode loss caused by a cover plate. By disposing the first light modulation layer 26 between the first inorganic packaging layer 241 and the organic packaging layer 242, the distance between the first light modulation layer 26 and the light-emitting unit 23 is shorter, such that the light rays emitted from the light-emitting units 23 are collimated by the first light modulation layer 26 at a shorter optical path and incidents to a film layer on a side of the first light modulation layer 26 distal from the substrate 21, thereby improving the uniformity of the luminance and the homogeneity of color cast at different viewing angles.

In addition, the difference between the refractive index of the first low-refractive layer 261 and the refractive index of the organic packaging layer 242 is greater than 0.1, and the refractive index of the first low-refractive layer 261 is smaller than that of the organic packaging layer 242. Combined with the curved surface appearance of the second concave curved surface structure 2611, the light rays are refracted in a direction towards the normal, that is, the light rays are collimated. The difference between the refractive index of the first low-refractive layer 261 and the refractive index of the organic packaging layer 242 is smaller, such that the loss of the light rays caused by an excessive refractive index of the organic packaging layer 242 is avoided, thereby effectively improving the light-emitting efficiency of the front surface and improving the luminance of the display panel. In some exemplary embodiments, the refractive index of the first low-refractive layer 261 ranges from 1.45 to 1.55, and the refractive index of the organic packaging layer 242 ranges from 1.65 to 1.85. In this way, the refractive index of the first low-refractive layer 261 is smaller than that of the organic packaging layer 242, and the difference between the refractive indexes is smaller.

The display panel according to the embodiments of the present disclosure may further include a second light modulation layer to further collimate divergent light rays emitted from light-emitting units. In some exemplary embodiments, please refer to FIG. 7, which is a schematic structural diagram of another display panel including a second light modulation layer according to some embodiments of the present disclosure. The display panel 20 includes a substrate 21, an insulating layer 22, a plurality of light-emitting units 23, a packaging layer 24, pixel definition layers 25 and a first light modulation layer 26. Please refer to the embodiment of FIG. 6 for details.

The display panel 20 further includes a second light modulation layer 27. The second light modulation layer 27 is disposed on a side of the packaging layer 24 distal from the substrate 21, and includes a second high-refractive layer 272 and a second low-refractive layer 271 which are laminated, and a refractive index of the second low-refractive layer 271 is smaller than that of the second high-refractive layer 272. A surface of the second low-refractive layer 271 proximal to the substrate 21 is provided with a plurality of third concave curved surface structures 2711 recessed towards the direction distal from the substrate 21, and a surface of the second high-refractive layer 272 distal from the substrate 21 is provided with a plurality of third convex curved surface structures 2721 protruding towards the direction distal from the substrate 21.

According to Snell's law, since the refractive index of the second low-refractive layer 271 is smaller than that of the second high-refractive layer 272, an incident angle is smaller than a refraction angle. Combined with the curved surface appearance of the third convex curved surface structure 2721, after reaching the second light modulation layer 27, the light rays will exit in a direction deviating from the normal. That is, part of the light rays are collimated by the second light modulation layer 27. Therefore, the light-emitting efficiency of the front surface is improved.

The third concave curved surface structure 2711 and the third convex curved surface structure 2721 are complementary structures, and the third convex curved surface structure 2721 is disposed in the third concave curved surface structure 2711. In this way, it is ensured that the second low-refractive layer 271 and the second high-refractive layer 272 are closely attached to each other, thereby avoiding the light ray loss caused by a gap.

The orthographic projection of the light-emitting unit 23 on the substrate 21 overlaps with the orthographic projection of the third concave curved surface structure 2711 of the second low-refractive layer 271 on the substrate 21. That is, a partial region of the light-emitting unit 23 directly faces the third concave curved surface structure 2711 of the second low-refractive layer 271. In this way, it can be ensured that part of the light rays emitted from the light-emitting unit 23 is collimated by the second light modulation layer 27.

In some embodiments, the orthogonal projection of the third concave curved surface structure 2711 of the second low-refractive layer 271 on the substrate 21 overlaps with the orthogonal projection of the second concave curved surface structure 2611 of the first low-refractive layer 261 on the substrate 21. That is, the second concave curved surface structure 2611 and the third concave curved surface structure 2711 have the same size, and moreover, curvatures of the second concave curved surface structure 2611 and the third concave curved surface structure 2711 may be the same, which is not limited in the present disclosure.

In some embodiments, the pixel definition layer 25 includes a reflective material, or the first inorganic packaging layer 241 covers the pixel definition layer 25 and the refractive index of the pixel definition layer 25 is smaller than that of the first inorganic packaging layer 241. Part of the wide-angle light rays emitted from the light-emitting units 23 irradiates the surface of the pixel definition layer 25, and when the pixel definition layer 25 includes the reflective material, this part of the light rays may be reflected by the pixel definition layer 25. In addition, there is a total reflection angle when light rays are emitted from a high-refractive material to a low-refractive material. When the light rays exceed this angle, total reflection will occur, and the greater the refractive index difference is, the smaller the total reflection angle is, and more light rays will be totally reflected. Therefore, the refractive index of the pixel definition layer 25 is smaller than that of the first inorganic packaging layer 241, such that part of the light rays irradiated on the surface of the pixel definition layer 25 can be reflected by the pixel definition layer 25, and the reflected light rays can reach the second light modulation layer 27 and then be refracted in a direction deviating from the normal. That is, the reflected light rays can be collimated by the second light modulation layer 27, such that the light-emitting efficiency of the front surface can be improved. The refractive index of the first inorganic packaging layer 241 ranges from 1.7 to 1.85, and the refractive index of the pixel definition layer 25 ranges from 1.4 to 1.55. The difference between the refractive index of the first inorganic packaging layer 241 and that of the pixel definition layer 25 is greater than or equal to 0.3, such that the total reflection angle is smaller, thereby enabling more light rays to be totally reflected by the pixel definition layer 25.

In some embodiments, the orthographic projections of the light-emitting unit 23 on the substrate 21 are disposed in the orthographic projection of the third concave curved surface structure 2711 on the substrate 21, and an orthographic projection of an edge of the light-emitting unit 23 on the substrate 21 is spaced from an orthographic projection of an edge of the curved surface structure 221 on the substrate 21. That is, the whole region of the light-emitting unit 23 directly faces the third concave curved surface structure 2711, and the maximum width of the third concave curved surface structure 2711 is larger than the light-emitting unit. In this way, it can be ensured that the third concave curved surface structure 2711 collects more light rays reflected by the pixel definition layer 25.

In some embodiments, for the display panel shown in FIGS. 5 to 7, the orthographic projection of the light-emitting unit 23 on the substrate 21 may also be disposed in the orthographic projection of the second concave curved surface structure 2611 of the first low-refractive layer 261 on the substrate 21, and the orthographic projection of the edge of the light-emitting unit 23 on the substrate 21 is spaced from the orthographic projection of the edge of the second concave curved surface structure 2611 on the substrate 21. In this way, the whole region of the light-emitting unit 23 directly faces the second concave curved surface structure 2611 of the first low-refractive layer 261, and the maximum width v2 of the second concave curved surface structure 2611 of the first low-refractive layer 261 is greater than the maximum width of the light-emitting unit 23, such that more light rays emitted from the light-emitting unit 23 can be further collimated by the first light modulation layer 26.

The maximum width v2 of the second concave curved surface structure 2611 of the first low-refractive layer 261 is equal to the maximum distance between one side of the adjacent pixel definition layers 25 distal from the substrate 21, which is not limited in the embodiments of the present disclosure. In addition, the light-emitting unit 23, the second concave curved surface structure 2611, and the third concave curved surface structure 2711 may have the same curvature, which is not limited in the present disclosure.

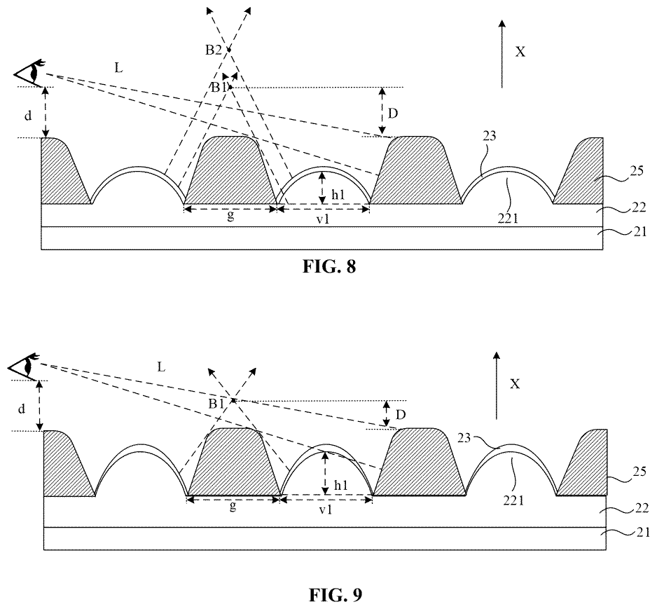

In some embodiments, the display panel shown in FIGS. 5 to 7 satisfies: h1/v1≤h2/v2<0.5. Please refer to FIG. 8, which is a schematic partial structural diagram of another display panel according to some embodiments of the present disclosure. Here, h1 is the maximum height difference between the region of the surface of the insulating layer 22 distal from the substrate 21 that has the curved surface structures 221 and the region of the surface of the insulating layer 22 distal from the substrate 21 that does not have the curved surface structure 221 in the first direction X perpendicular to the substrate 21. Specifically, for the case that the curved surface structure 221 is a first convex curved surface structure, h1 is the distance between the top of the first convex curved surface structure and the region of the insulating layer 22 that does not have the curved surface structure 221 in the first direction X. For the case that the curved surface structure 221 is the first concave curved surface structure, h1 is the distance between the bottom of the first concave curved surface structure and the region of the insulating layer 22 that does not have the curved surface structure 221 in the first direction X. Here, v1 is the maximum width of the curved surface structure 221 of the insulating layer 22 in a direction parallel to the substrate 21, h2 is the maximum height difference between a region of a surface of the first low-refractive layer 261 distal from the substrate 21 that has the second concave curved surface structures 2611 and a region of the surface of the first low-refractive layer 261 that does not have the second concave curved surface structure 2611 in the first direction X, and v2 is the maximum width of the second concave curved surface structure 2611 of the first low-refractive layer 261 in the direction parallel to the substrate 21.

By limiting a height-width ratio h1/v1 of the curved surface structure 221, a problem of color mixing likely caused by a larger difference between h1 and v1 is avoided. Please refer to FIG. 9, which is a schematic partial structural diagram of another display panel according to some embodiments of the present disclosure, in which the difference between h1 and v1 is larger. When the height of a human eye is larger than the height d of the display panel, the color mixing crosstalk generated by two adjacent light-emitting units 23 with different colors can be observed at a larger viewing angle, which may cause the color cast to deteriorate. As a result, the display effect of the display panel is adversely influenced. In some exemplary embodiments, the range of h1 is: 0 micron<h1<2 micron. When h1 is greater than 0 microns, it can be ensured that the insulating layer 22 includes the curved surface structure 221. When h1 is less than two microns, please refer to FIG. 7, which can avoid the color mixing crosstalk when observing at a large viewing angle.

In addition, by defining a height-width ratio h2/v2 of the second concave curved surface structure 2611 of the first low-refractive layer 261 to be greater than or equal to the height-width ratio h1/v1 of the curved surface structure 221, it is ensured that the second concave curved surface structure 2611 can collect more divergent light rays emitted from the light-emitting unit 23. In some exemplary embodiments, in the display panel shown in FIGS. 4 to 6, the height-width ratio h2/v2 of the second concave curved surface structure 2611 is equal to the height-width ratio h1/v1 of the curved surface structure 221, and the curvatures thereof are equal. In this way, it can further ensure that the second concave curved surface structure 2611 collimates the divergent light rays emitted from the light-emitting unit 23.

In some embodiments, the display panel shown in FIGS. 5 to 7 satisfies: H<D=tan (v1/2 h1)*(g+v1)/2. Please refer to FIG. 8, H is the minimum distance between the second concave curved surface structure 2611 of the first low-refractive layer 261 and the light-emitting units 23 in the first direction X; and D is the minimum distance between a color mixing point and the pixel definition layer 25 in the first direction X, and the color mixing point is a point at which light rays that do not irradiate the pixel definition layer 25 in light rays emitted from the two adjacent light-emitting units 23 in the plurality of light-emitting units 23 intersect. In fact, there is a plurality of color mixing points, such as a color mixing point B1 and a color mixing point B2. The color mixing point B1 is the closest color mixing point to the pixel definition layer 25, and the distance between the color mixing point B1 and the pixel definition layer 25 in the first direction X is the minimum distance D between the color mixing point and the pixel definition layer 25 in the first direction X. Here, h1 is a maximum height difference between the region of the surface of the insulating layer 22 distal from the substrate 21 that has the curved surface structures 221 and the region of the surface of the insulating layer 21 distal from the substrate 21 that does not have the curved surface structure 211 in the first direction X; v1 is the maximum width of the curved surface structures of the insulating layer in a direction parallel to the substrate; and g is the distance between the two adjacent light-emitting units in the direction parallel to the substrate.

By setting the minimum distance H between the second concave curved surface structure 2611 and the light-emitting unit 23 in the first direction X to be smaller than the minimum distance D between the color mixing point and the pixel definition layer 25 in the first direction X, the height of the second concave curved surface structure 2611 is smaller than the height of the color mixing point B1 closest to the pixel definition layer 25, such that the first light modulation layer 26 collimates light rays before the light rays are mixed, thereby preventing the light rays of two adjacent light-emitting units 23 from being mixed to adversely affect the display effect of the display panel 20.

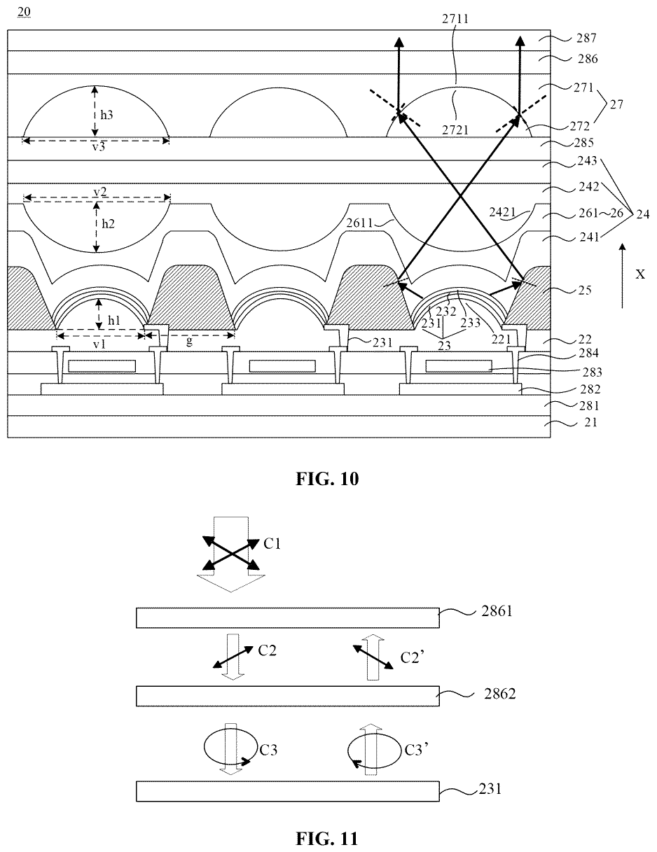

Based on the display panel shown in FIG. 7, another display panel having other functional layers is provided by the present disclosure. Please refer to FIG. 10, which is a schematic structural diagram of another display panel having other functional layers according to some embodiments of the present disclosure. The display panel 20 includes a substrate 21, an insulating layer 22, a plurality of light-emitting units 23, a packaging layer 24, a pixel definition layer 25, a first light modulation layer 26, and a second light modulation layer 27. Please refer to the embodiment of FIG. 7 for details.

The display panel 20 further includes other functional layers: a buffer layer 281, a polysilicon layer 282, a gate electrode 283, a source/drain electrode 284, a touch layer 285, a polarization structure layer 286, and a cover plate 287.

The buffer layer 281 is disposed on a side of the substrate 21 proximal to the insulating layer 22, and prevents water and oxygen from eroding the conductive circuits and flattens the surface of the display panel. The polysilicon layer 282 is disposed on a side of the buffer layer 281 distal from the substrate 21. The gate electrode 283 and the source/drain electrode 284 are disposed on a side of the polysilicon layer 282 distal from the buffer layer 281. The source/drain electrode 284 is electrically connected to the first electrode layer 231 and the gate electrode 283, so as to transmit an electrical signal to the first electrode layer 231.

The touch layer 285 is disposed between the second inorganic packaging layer 243 and the second high-refractive layer 272. The touch layer 285 is an integrated touch layer, such that the touch layer 285 is integrated with other film layers, and the display panel is developed to be thinner and more light-weight based on the fact that the display panel has a touch function.

The polarization structure layer 286 is disposed on a side of the second low-refractive layer 271 distal from the second high-refractive layer 272, reduces the reflectivity of ambient light rays, ensures the contrast of the display panel in different external environments, and reduces reflection of the display panel on the ambient light rays, so as to achieve an excellent display effect. The polarization structure layer 286 includes a polarizing plate 2861 and a quarter-wave plate 2862. Please refer to FIG. 11, which is a schematic principal diagram of a polarization structure layer according to some embodiments of the present disclosure. Ambient light C1 is changed into linear polarized light C2 via the polarizing plate 2861, and then into circular polarized light C3 via the quarter-wave plate 2862. After being reflected by the first electrode layer 231, a vector component of the circular polarized light C3 generates half-wave loss. A rotation direction of synthesized circular polarized light C3′ is deflected, and reflected linear polarized light C2′ perpendicular to the incident linear polarized light C2 is generated after the synthesized circular polarized light C3′ passes through the quarter-wave plate 2862. Since the polarization direction of the reflected linear polarized light C2′ is different from that of the polarizing plate 2861, the reflected light is limited in the display panel, which reduces the reflectivity of the ambient light.

The cover plate 287 is disposed on a side of the polarization structure layer 286 distal from the second low-refractive layer 271, and the cover plate 287 may include a glass cover plate.

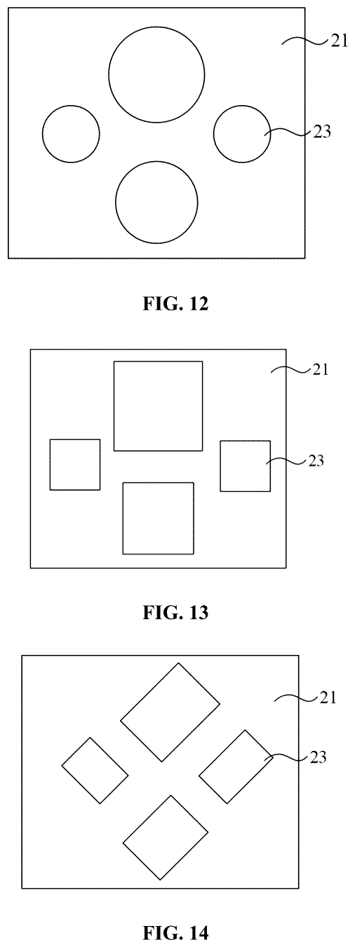

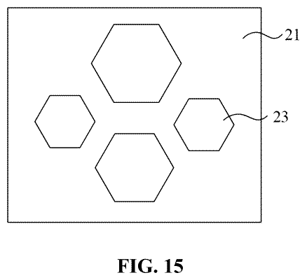

Various shapes and arrangements of light-emitting units are applicable in the embodiments of the present disclosure. In some exemplary embodiments, the shape of the light-emitting unit according to the embodiments of the present disclosure may be a circle, quadrangle, hexagon, or the like having a curved surface structure. Please refer to FIGS. 12 to 15. FIG. 12 is a schematic top view of circular light-emitting units having curved surface structures; FIG. 13 is a schematic top view of square light-emitting units having curved surface structures; FIG. 14 is a schematic top view of rectangular light-emitting units having curved surface structures; and FIG. 15 is a schematic top view of hexagonal light-emitting units having curved surface structures. Each of the light-emitting units 23 in FIGS. 12 to 15 may have the curved surface structure which may be a convex curved surface structure, a concave curved surface structure, or both. Compared with a light-emitting unit in the shape of the planar surface, the light-emitting unit 23 in the shape of the curved surface has a larger light-emitting area, such that the luminance is improved, and a problem of poorer luminance of display panels in the related art is solved, thereby achieving an effect of improving the luminance of the display panel. In addition, the light-emitting unit of the curved surface according to the embodiments of the present disclosure may be applied to diamond-like pixel arrangement, GGRB pixel arrangement, real RGB pixel arrangement, or the like.

The light-emitting unit structure of the curved surface according to the embodiments of the present disclosure is applied not only to the display field of pixel structures, but also to the lighting field for improving the luminance of light at different angles, such as automobile lamps and other fields. The light-emitting unit of the curved surface can significantly improve the luminance at the full viewing angle.

In summary, a display panel including a substrate, an insulating layer, and a plurality of light-emitting units is provided according to the embodiments of the present disclosure, wherein a surface of the insulating layer distal from the substrate has a plurality of curved surface structures, and the plurality of light-emitting units is disposed on the plurality of curved surface structures in one-to-one correspondence. In this way, an electrode and a light-emitting layer of the light-emitting unit disposed on the corresponding curved surface structure are in the shape of a curved surface, and the electrode drives the light-emitting layer in the shape of the curved surface to emit light rays. Compared with a light-emitting unit in the shape of a planar surface, the light-emitting unit in the shape of a curved surface has a larger light-emitting area, such that the luminance is improved, and a problem of poorer luminance of display panels in the related art is solved, thereby achieving an effect of improving the luminance of the display panel.

In addition, in the case that the curved surface structure of the insulating layer is the convex curved surface structure, the distance between the light-emitting unit and the conductive circuit is lengthened. In the case that the curved surface structure of the insulating layer is the concave curved surface structure, since the concave curved surface structure is manufactured by etching the flat insulating layer, the appearance of the bottom of the concave curved surface structure is not affected by the conductive circuit. Therefore, in both cases, the adverse influence of the conductive circuit on the surface homogeneity of the light-emitting unit is avoided, such that the uniformity of the luminance of the display panel and the homogeneity of color cast at different viewing angles is improved.

In addition, a display apparatus is further provided according to some embodiments of the present disclosure. The display apparatus includes a housing and any one of the display panels according to the above embodiments, and the display panel is disposed in the housing. The display apparatus may be various apparatuses including a display function, such as displayers, televisions, vertical advertising machines, screen painting apparatuses, mobile phones, various smart wearable devices, and the like.

Since the display apparatus includes the display panel according to the above embodiments, the display apparatus has a similar effect, namely, the effect of improving the luminance of the display apparatus and the light-emitting efficiency of the front surface of the display apparatus.

The term “at least one of A or B” in the present disclosure only describes an association relationship between associated objects, and indicates that there may be three kinds of relationships. For example, at least one of A or B may indicate three cases: A exists alone, A and B exist at the same time, and B exists alone.

It should be noted that in the accompanying drawings, the dimensions of the layers and parts may be exaggerated for the clarity of the drawings. Moreover, it can be understood that when an element or layer is named to be disposed “on” another element or layer, the element or layer may be directly disposed on the another element, or there may be an intermediate layer. In addition, it can be understood that when an element or layer is named to be disposed “under” another element or layer, the element or layer may be directly disposed under the another element, or there may be at least one intermediate layer or element. In addition, it can be understood that when an element or layer is named to be disposed “between” two layers or two elements, the element or layer may be the exclusive one between the two layers or two elements, or there may be at least one intermediate layer or element. Similar reference signs refer to similar elements throughout the whole text.

In the present disclosure, the terms “first”, “second” and “third” are only used for a descriptive purpose, and shall not be understood as indicating or implying relative importance. Unless otherwise expressly defined, the term “a plurality of” means two or more.

The foregoing descriptions are merely optional embodiments of the present disclosure, and are not intended to limit the present disclosure. Within the spirit and principles of the present disclosure, any modifications, equivalent substitutions, improvements, etc., are within the protection scope of the present disclosure.

1. A display panel, comprising:
a substrate;
an insulating layer disposed on the substrate, wherein a surface, distal from the substrate, of the insulating layer is provided with a plurality of curved surface structures; and
a plurality of light-emitting units disposed on the plurality of curved surface structures in one-to-one correspondence, wherein each of the light-emitting units comprises a first electrode layer, a light-emitting layer and a second electrode layer, the first electrode layer is disposed on a curved surface structure corresponding to the light-emitting unit, the light-emitting layer is disposed on a side, distal from the curved surface structure, of the first electrode layer, and the second electrode is disposed on a side, distal from the curved surface structure, of the light-emitting layer.

2. The display panel according to claim 1, wherein the plurality of curved surface structures comprises first convex curved surface structures protruding towards a direction distal from the substrate, first concave curved surface structures recessed towards a direction proximal to the substrate, or both.

3. The display panel according to claim 2, further comprising: a first light modulation layer disposed on a side, distal from the substrate, of the light-emitting units, wherein the first light modulation layer comprises a first low-refractive layer and a first high-refractive layer which are laminated, the first high-refractive layer is disposed on a side, distal from the substrate, of the first low-refractive layer, and a refractive index of the first low-refractive layer is smaller than a refractive index of the first high-refractive layer; and
a surface, distal from the substrate, of the first low-refractive layer is provided with second concave curved surface structures recessed towards the direction proximal to the substrate, and a surface, proximal to the substrate, of the first high-refractive layer is provided with second convex curved surface structures protruding towards the direction proximal to the substrate, the second concave curved surface structures and the second convex curved surface structures are complementary structures, and the second convex curved surface structures are disposed in the second concave curved surface structures; and
orthogonal projections of the light-emitting units on the substrate overlap with orthogonal projections of the second concave curved surface structures of the first low-refractive layer on the substrate.

4. The display panel according to claim 3, further comprising: a packaging layer disposed on the side, distal from the substrate, of the light-emitting units, and the first light modulation layer is disposed on a side, distal from the light-emitting units, of the packaging layer.

5. The display panel according to claim 2, further comprising: a packaging layer and a first light modulation layer, wherein the packaging layer comprises a first inorganic packaging layer, an organic packaging layer, and a second inorganic packaging layer which are laminated on the side, distal from the substrate, of the light-emitting units, the first light modulation layer is disposed between the first inorganic packaging layer and the organic packaging layer, and comprises a first low-refractive layer, and a refractive index of the first low-refractive layer is smaller than a refractive index of the organic packaging layer; and
a surface, distal from the substrate, of the first low-refractive layer is provided with second concave curved surface structures recessed towards the direction proximal to the substrate, a surface, proximal to the substrate, of the organic packaging layer is provided with second convex curved surface structures protruding towards the direction proximal to the substrate, the second concave curved surface structures and the second convex curved surface structures are complementary structures, and the second convex curved surface structures are disposed in the second concave curved surface structures;
orthogonal projections of the light-emitting units on the substrate overlap with orthogonal projections of the second concave curved surface structures of the first low-refractive layer on the substrate.

6. The display panel according to claim 5, further comprising: a second light modulation layer, disposed on a side, distal from the substrate, of the packaging layer, wherein the second light modulation layer comprises a second high-refractive layer and a second low-refractive layer which are laminated, and a refractive index of the second low-refractive layer is smaller than a refractive index of the second high-refractive layer; and
a surface, proximal to the substrate, of the second low-refractive layer is provided with third concave curved surface structures recessed towards the direction distal from the substrate, a surface, distal from the substrate, of the second high-refractive layer is provided with third convex curved surface structures protruding towards the direction distal from the substrate, the third concave curved surface structures and the third convex curved surface structures are complementary structures, and the third convex curved surface structures are disposed in the third concave curved surface structures; and
the orthogonal projections of the light-emitting units on the substrate overlap with orthogonal projections of the third concave curved surface structures of the second low-refractive layer on the substrate.

7. The display panel according to claim 6, wherein the orthogonal projections of the third concave curved surface structures of the second low-refractive layer on the substrate overlap with the orthogonal projections of the second concave curved surface structures of the first low-refractive layer on the substrate.

8. The display panel according to claim 6, further comprising: a pixel definition layer, disposed in a region of the surface, distal from the substrate, of the insulating layer that does not have the curved surface structure; and
the pixel definition layer comprises a reflective material, or the first inorganic packaging layer covers the pixel definition layer and a refractive index of the pixel definition layer is smaller than a refractive index of the first inorganic packaging layer.

9. The display panel according to claim 3, wherein the orthographic projections of the light-emitting units on the substrate are disposed in the orthographic projections of the second concave curved surface structures on the substrate, and an orthographic projection of an edge of each light-emitting unit on the substrate is spaced from an orthographic projection of an edge of a second concave curved surface structure corresponding to the light-emitting unit on the substrate.

10. The display panel according to claim 3, wherein the display panel satisfies: h1/v1≤h2/v2<0.5,
wherein h1 is a maximum height difference between a region of the surface, distal from the substrate, of the insulating layer that has the curved surface structures and a region of the surface, distal from the substrate, of the insulating layer that does not have the curved surface structure in a first direction perpendicular to the substrate, v1 is a maximum width of the curved surface structures of the insulating layer in a direction parallel to the substrate, h2 is a maximum height difference between a region of the surface, distal from the substrate, of the first low-refractive layer that has the second concave curved surface structures and a region of the surface, distal from the substrate, of the first low-refractive layer that does not have the second concave curved surface structure in the first direction, and v2 is a maximum width of the second concave curved surface structures of the first low-refractive layer in the direction parallel to the substrate.

11. The display panel according to claim 3, further comprising: a pixel definition layer disposed on a side, distal from the substrate, of the insulating layer, and the pixel definition layer is disposed between the plurality of curved surface structures; and
the display panel satisfies: H<D=tan (v1/2 h1)*(g+v1)/2, wherein H is a minimum distance between the second concave curved surface structures of the first low-refractive layer and the light-emitting units in a first direction perpendicular to the substrate; D is a minimum distance between a color mixing point and the pixel definition layer in the first direction, and the color mixing point is a point at which light rays that do not irradiate the pixel definition layer in light rays emitted from the two adjacent light-emitting units in the plurality of light-emitting units intersect; h1 is a maximum height difference between the region of the surface, distal from the substrate, of the insulating layer that has the curved surface structures and the region of the surface, distal from the substrate, of the insulating layer that does not have the curved surface structure in the first direction; v1 is a maximum width of the curved surface structures of the insulating layer in a direction parallel to the substrate; and g is a distance between two adjacent light-emitting units in the direction parallel to the substrate.

12. The display panel according to claim 2, wherein the surface, distal from the substrate, of the insulating layer is provided with a plurality of first concave curved surface structures recessed towards the direction proximal to the substrate; and
a thickness of a region of the surface, distal from the substrate, of the insulating layer that does not have the curved surface structure ranges from 3 microns to 5 microns, and a thickness of a region of the surface, distal from the substrate, of the insulating layer that has the curved surface structures is greater than or equal to 1 micron.

13. The display panel according to claim 1, wherein a maximum height difference between a region of the surface, distal from the substrate, of the insulating layer that has the curved surface structures and a region of the surface, distal from the substrate, of the insulating layer that does not have the curved surface structure in a first direction perpendicular to the substrate is greater than 0 micron and less than or equal to 2 microns.

14. The display panel according to claim 1, further comprising: conductive circuits disposed on the substrate, wherein the insulating layer covers the conductive circuits, and orthogonal projections of the curved surface structures on the substrate overlap with orthogonal projections of the conductive circuits on the substrate.

15. A display apparatus, comprising: a housing and a display panel, wherein the display panel is disposed in the housing; and
the display panel comprises:
a substrate;
an insulating layer disposed on the substrate, wherein a surface, distal from the substrate, of the insulating layer is provided with a plurality of curved surface structures; and
a plurality of light-emitting units disposed on the plurality of curved surface structures in one-to-one correspondence, wherein each of the light-emitting units comprises a first electrode layer, a light-emitting layer and a second electrode layer, the first electrode layer is disposed on a curved surface structure corresponding to the light-emitting unit, the light-emitting layer is disposed on a side, distal from the curved surface structure, of the first electrode layer, and the second electrode is disposed on a side, distal from the curved surface structure, of the light-emitting layer.

16. The display apparatus according to claim 15, wherein the plurality of curved surface structures comprises first convex curved surface structures protruding towards a direction distal from the substrate, first concave curved surface structures recessed towards a direction proximal to the substrate, or both.

17. The display apparatus according to claim 16, wherein the display panel further comprises: a first light modulation layer disposed on a side, distal from the substrate, of the light-emitting units, wherein the first light modulation layer comprises a first low-refractive layer and a first high-refractive layer which are laminated, the first high-refractive layer is disposed on a side, distal from the substrate, of the first low-refractive layer, and a refractive index of the first low-refractive layer is smaller than a refractive index of the first high-refractive layer; and
a surface, distal from the substrate, of the first low-refractive layer is provided with second concave curved surface structures recessed towards the direction proximal to the substrate, and a surface, proximal to the substrate, of the first high-refractive layer is provided with second convex curved surface structures protruding towards the direction proximal to the substrate, the second concave curved surface structures and the second convex curved surface structures are complementary structures, and the second convex curved surface structures are disposed in the second concave curved surface structures; and
orthogonal projections of the light-emitting units on the substrate overlap with orthogonal projections of the second concave curved surface structures of the first low-refractive layer on the substrate.

18. The display apparatus according to claim 17, wherein the display panel further comprises: a packaging layer disposed on the side, distal from the substrate, of the light-emitting units, and the first light modulation layer is disposed on a side, distal from the light-emitting units, of the packaging layer.

19. The display apparatus according to claim 16, wherein the display panel further comprises: a packaging layer and a first light modulation layer, wherein the packaging layer comprises a first inorganic packaging layer, an organic packaging layer, and a second inorganic packaging layer which are laminated on the side, distal from the substrate, of the light-emitting units, the first light modulation layer is disposed between the first inorganic packaging layer and the organic packaging layer, and comprises a first low-refractive layer, and a refractive index of the first low-refractive layer is smaller than a refractive index of the organic packaging layer; and
a surface, distal from the substrate, of the first low-refractive layer is provided with second concave curved surface structures recessed towards the direction proximal to the substrate, a surface, proximal to the substrate, of the organic packaging layer is provided with second convex curved surface structures protruding towards the direction proximal to the substrate, the second concave curved surface structures and the second convex curved surface structures are complementary structures, and the second convex curved surface structures are disposed in the second concave curved surface structures;
orthogonal projections of the light-emitting units on the substrate overlap with orthogonal projections of the second concave curved surface structures of the first low-refractive layer on the substrate.

20. The display apparatus according to claim 19, wherein the display panel further comprises: a second light modulation layer, disposed on a side, distal from the substrate, of the packaging layer, wherein the second light modulation layer comprises a second high-refractive layer and a second low-refractive layer which are laminated, and a refractive index of the second low-refractive layer is smaller than a refractive index of the second high-refractive layer; and
a surface, proximal to the substrate, of the second low-refractive layer is provided with third concave curved surface structures recessed towards the direction distal from the substrate, a surface, distal from the substrate, of the second high-refractive layer is provided with third convex curved surface structures protruding towards the direction distal from the substrate, the third concave curved surface structures and the third convex curved surface structures are complementary structures, and the third convex curved surface structures are disposed in the third concave curved surface structures; and
the orthogonal projections of the light-emitting units on the substrate overlap with orthogonal projections of the third concave curved surface structures of the second low-refractive layer on the substrate.
